(19) United States
(12) Patent Application Publication
(10) Pub. No.: US 2017/0159830 A1
(43) Pub. Date: Jun. 8, 2017

(54) RECTANGULAR GATE VACUUM VALVE ASSEMBLY, AND SEMICONDUCTOR MANUFACTURING APPARATUS INCLUDING THE ASSEMBLY

(71) Applicant: FUGEN CO., LTD., Yongin-si (KR)

(72) Inventors: Heejun AHN, Pyeongtaek-si (KR); Jootaek KIM, Yongin-si (KR)

(21) Appl. No.: 15/321,945

(22) PCT Filed: Mar. 24, 2016
(86) PCT No.: PCT/KR2016/002986

§ 371 Date: Dec. 23, 2016

(30) Foreign Application Priority Data
Jun. 19, 2015 (KR) 10-2015-0087703

(51) Int. Cl. F16K 3/18; H01L 21/677; H01L 21/02; F16K 25/00; F16K 51/02

(52) U.S. Cl. CPC F16K 3/18; F16K 25/00; F16K 51/02; H01L 21/02; H01L 21/677

(57) ABSTRACT

The rectangular gate vacuum valve assembly comprises a gate frame having an inner space defined therein, wherein the gate frame has opposite side walls and opposite top and bottom walls, wherein the gate frame has opposite first and second gates defined in the opposite side walls respectively, wherein the gate frame has first and second holes defined in one of the top and bottoms walls, wherein the first and second holes are spaced from each other, wherein the other of the top and bottoms walls is entirely blocked; a first valve mechanism configured to translate through the first hole in the inner space and/or to rotate in the inner space to selectively open or close the first gate; and a second valve mechanism configured to translate through the second hole in the inner space and/or to rotate in the inner space to selectively open or close the second gate.

### BACKGROUND

Field of the Present Disclosure

The present disclosure relates to a rectangular gate vacuum valve assembly, a method for operating the assembly and a semiconductor manufacturing apparatus including the assembly. More particularly, the present disclosure relates to a rectangular gate vacuum valve assembly to seal opposite first and second gates defined in the same limited space, which may be useful when the opposite first and second gates defined in the same limited space should be sealed for the semiconductor manufacturing process, and one of the bottom and top walls of is completely blocked.

Discussion of the Related Art

The semiconductor should be manufactured in a clean room for a high precision.

The semiconductor manufacturing process should be carried out in a vacuum state in order to prevent the semiconductor from being polluted by contaminants in an air.

The semiconductor manufacturing facility may have a gate valve to selectively form a vacuum state in a chamber.

Among various gate valves, a rectangular gate vacuum valve has been generally employed.

The rectangular gate vacuum valve may be applied not only to the semiconductor manufacturing process but also to a LCD manufacturing process. The rectangular gate vacuum valve may be disposed between a process chamber and transfer chamber, or between a transfer chamber and load lock chamber.

The vacuum valve may be classified into uni-directional and bi-directional valves.

The rectangular gate vacuum valve may open or close a rectangular gate using a disk thereof.

Regarding an operation of the gate vacuum valve, a main shaft with a disk is lifted up into the gate frame (close mode), and is pushed toward to close the gate (push mode), and is withdrawn from the gate frame to open the gate (open mode).

Those close, push and open modes may be repeated to allow or disallow the vacuum sate.

The rectangular gate vacuum valve may be operated by a translation movement and rotation at a highest level.

A currently available rectangular gate vacuum valve is configured to open or close only one side gate at the gate frame.

Thus, the present applicant files another pending application disclosing the gate frame having first and second holes defined in the opposite top and bottom walls thereof respectively, wherein a first valve mechanism translates through the first hole and a second valve mechanism translates through the second hole.

However, for this pending application, since the first and second holes are defined in the opposite top and bottom walls of the gate frame respectively, this leads to an increase in the height of the gate frame. Thus, this approach may not be applied to a case wherein a space above or below the opposite top or bottom wall is not available.

### SUMMARY

The present disclosure is to provide a rectangular gate vacuum valve assembly to seal opposite first and second gates defined in the same limited space, which may be useful when the opposite first and second gates defined in the same limited space should be sealed for the semiconductor manufacturing process, and one of the bottom and top walls of is completely blocked.

In one aspect, there is provided a rectangular gate vacuum valve assembly comprising: a gate frame having an inner space defined therein, wherein the gate frame has opposite side walls and opposite top and bottom walls, wherein the gate frame has opposite first and second gates defined in the opposite side walls respectively, wherein the gate frame has first and second holes defined in one of the top and bottoms walls, wherein the first and second holes are spaced from each other, wherein the other of the top and bottoms walls is entirely blocked; a first valve mechanism configured to translate through the first hole in the inner space and/or to rotate in the inner space to selectively open or close the first gate; and a second valve mechanism configured to translate through the second hole in the inner space and/or to rotate in the inner space to selectively open or close the second gate.

In one implementation, the first valve mechanism comprises: a first disk configured to selectively open or close the first gate; a first shaft coupled to the first disk to translate the first disk; and a first rotation unit coupled to the first shaft to rotate the first shaft.

In one implementation, the second valve mechanism comprises: a second disk configured to selectively open or close the second gate; a second shaft coupled to the second disk to translate the second disk; and a second rotation unit coupled to the second shaft to rotate the second shaft.

In one implementation, each of the first and second disks has a sealing ring attached thereto.

In one implementation, the first and second gates have the same size or different sizes.

In one aspect, there is provided a system for a rectangular gate vacuum valve assembly, the system comprising: the above-defined assembly; a signal generator configured to generate a control signal to allow closing and opening of the first and second gates; and a controller configured to control operations of the first and second valve mechanisms based on the control signal from the signal generator.

In one aspect, there is provided a semiconductor manufacturing apparatus comprising: first and second vacuum chambers spaced from each other where a semiconductor manufacturing process is conducted; and a rectangular gate vacuum valve assembly disposed between the first and second vacuum chambers, wherein the rectangular gate vacuum valve assembly is configured to selectively close or open first and second gates communicating with the first and second vacuum chambers respectively, wherein the rectangular gate vacuum valve assembly comprises: a gate frame having an inner space defined therein, wherein the gate frame has opposite side walls and opposite top and bottom walls, wherein the gate frame has the opposite first and second gates defined in the opposite side walls respectively, wherein the gate frame has first and second holes defined in one of the top and bottoms walls, wherein the first and second holes are spaced from each other, wherein the other of the top and bottoms walls is entirely blocked; a first valve mechanism configured to translate through the first hole in the inner space and/or to rotate in the inner space to selectively open or close the first gate; and a second valve mechanism configured to translate through the second hole in the inner space and/or to rotate in the inner space to selectively open or close the second gate.

In one implementation, the first valve mechanism comprises: a first disk configured to selectively open or close the first gate; a first shaft coupled to the first disk to translate the first disk; and a first rotation unit coupled to the first shaft to rotate the first shaft, wherein the second valve mechanism comprises: a second disk configured to selectively open or close the second gate; a second shaft coupled to the second disk to translate the second disk; and a second rotation unit coupled to the second shaft to rotate the second shaft, wherein each of the first and second disks has a sealing ring attached thereto.

The present rectangular gate vacuum valve assembly may seal the opposite first and second gates defined in the same limited space. Thus, this may be useful when the opposite first and second gates defined in the same limited space should be sealed for the semiconductor manufacturing process. Further, this approach may be applied to a case wherein a space above or below the opposite top or bottom wall is not available.

### BRIEF DESCRIPTION OF THE DRAWINGS

FIG. 1 is a diagram of a schematic structure of a semiconductor manufacturing apparatus in accordance with one embodiment of the present disclosure wherein a first gate is closed.

FIG. 2 is a diagram of a schematic structure of a semiconductor manufacturing apparatus in accordance with one embodiment of the present disclosure wherein a second gate is closed.

FIG. 3 is a diagram of a schematic structure of the rectangular gate vacuum valve assembly in accordance with one embodiment of the present disclosure, wherein the first and second gates are opened.

FIG. 4 to FIG. 7 illustrate operations of the rectangular gate vacuum valve assembly.

FIG. 8 is a block diagram of a system for controlling the rectangular gate vacuum valve assembly.

FIG. 9 is a flow chart of a method for operating the rectangular gate vacuum valve assembly in accordance with one embodiment of the present disclosure.

FIG. 10 is a diagram of a schematic structure of a rectangular gate vacuum valve assembly in accordance with another embodiment of the present disclosure, wherein the first and second gates are opened and a separate blocking plate is absent.

FIG. 11 to FIG. 13 illustrate operations of a rectangular gate vacuum valve assembly, in accordance with still another embodiment of the present disclosure.

FIG. 14 is a diagram of a schematic structure of a rectangular gate vacuum valve assembly in accordance with further still another embodiment of the present disclosure, wherein the first and second gates are closed.

### DETAILED DESCRIPTIONS

### Best Mode

In one embodiment, a rectangular gate vacuum valve assembly comprises

a gate frame having an inner space defined therein, wherein the gate frame has opposite side walls and opposite top and bottom walls, wherein the gate frame has opposite first and second gates defined in the opposite side walls respectively, wherein the gate frame has first and second holes defined in one of the top and bottoms walls, wherein the first and second holes are spaced from each other, wherein the other of the top and bottoms walls is entirely blocked; a first valve mechanism configured to translate through the first hole in the inner space and/or to rotate in the inner space to selectively open or close the first gate; and a second valve mechanism configured to translate through the second hole in the inner space and/or to rotate in the inner space to selectively open or close the second gate.

### Embodiments

Examples of various embodiments are illustrated in the accompanying drawings and described further below.

It will be understood that the description herein is not intended to limit the claims to the specific embodiments described. On the contrary, it is intended to cover alternatives, modifications, and equivalents as may be included within the spirit and scope of the present disclosure as defined by the appended claims.

The present disclosure, however, may be embodied in various different forms, and should not be construed as being limited to only the illustrated embodiments herein.

Rather, these embodiments are provided as examples so that this disclosure will be thorough and complete, and will fully convey the aspects and features of the present disclosure to those skilled in the art.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “connected to”, or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

Spatially relative terms, such as “beneath,” “below,” “lower,” “under,” “above,” “upper,” and the like, may be used herein for ease of explanation to describe one element or feature's relationship to another element s or feature s as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented for example, rotated 90 degrees or at other orientations, and the spatially relative descriptors used herein should be interpreted accordingly.

The terminology used herein is for the purpose of describing particular embodiments only and is not intended to be limiting of the present disclosure. As used herein, the singular forms “a” and “an” are intended to include the plural forms as well, unless the context clearly indicates otherwise.

It will be further understood that the terms “comprises”, “comprising”, “includes”, and “including” when used in this specification, specify the presence of the stated features, integers, s, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other instances, well-known process structures and/or processes have not been described in detail in order not to unnecessarily obscure the present disclosure.

Further, the use of “may” when describing embodiments of the present disclosure refers to “one or more embodiments of the present disclosure.”

Hereinafter, embodiments of the present disclosure will be described in details with reference to attached drawings, which are incorporated in and form a part of this specification and in which like numerals depict like elements, illustrate embodiments of the present disclosure and, together with the description, serve to explain the principles of the disclosure.

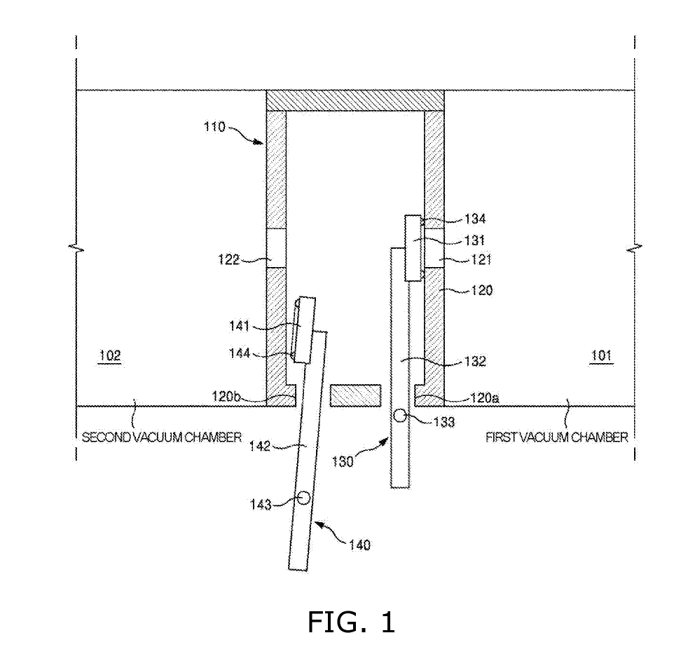

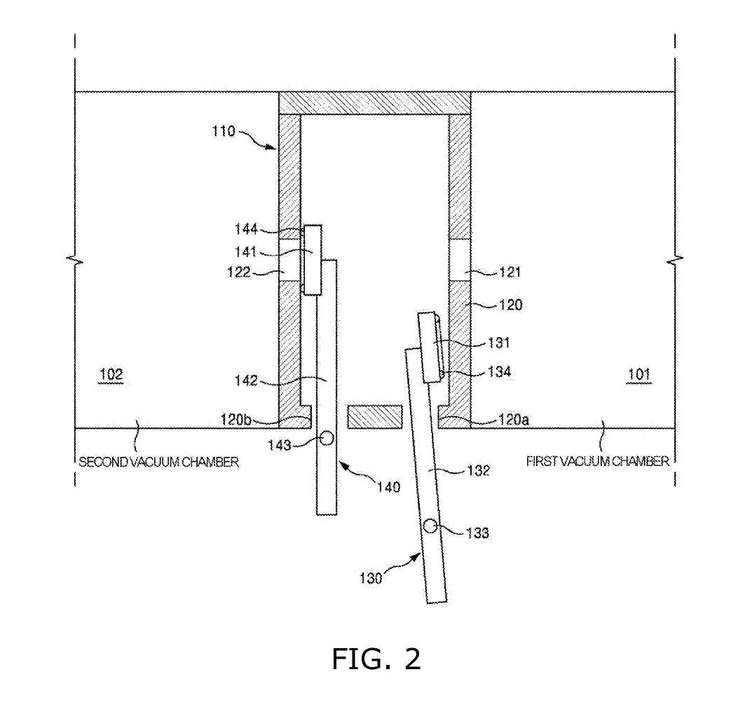

FIG. 1 is a diagram of a schematic structure of a semiconductor manufacturing apparatus in accordance with one embodiment of the present disclosure wherein a first gate is closed. FIG. 2 is a diagram of a schematic structure of a semiconductor manufacturing apparatus in accordance with one embodiment of the present disclosure wherein a second gate is closed.

Referring to FIG. 1 and FIG. 2, the semiconductor manufacturing apparatus in accordance with one embodiment of the present disclosure may include first and second vacuum chambers 101,102 spaced from each other where a semiconductor manufacturing process is conducted; and a rectangular gate vacuum valve assembly 110 disposed between the first and second vacuum chambers 101,102, wherein the rectangular gate vacuum valve assembly 110 may be configured to selectively close or open first and second gates 121,122 corresponding to the first and second vacuum chambers 101,102 respectively.

The first and second vacuum chambers 101,102 may have the same or different functions.

For example, the first and second vacuum chambers 101,102 may be a deposition chamber, a process chamber, a transfer chamber, or a loadlock chamber. The first and second vacuum chambers 101,102 may be used to manufacturing the display panel. The present disclosure may not be limited thereto.

The rectangular gate vacuum valve assembly 110 may be configured to selectively close or open first and second gates 121,122 corresponding to the first and second vacuum chambers 101,102 respectively. The first and second gates 121,122 may be communicated with the first and second vacuum chambers 101,102 respectively.

The rectangular gate vacuum valve assembly 110 may seal the opposite first and second gates 121,122 defined in the same limited space. Thus, this may be useful when the opposite first and second gates 121,122 defined in the same limited space should be sealed for the semiconductor manufacturing process.

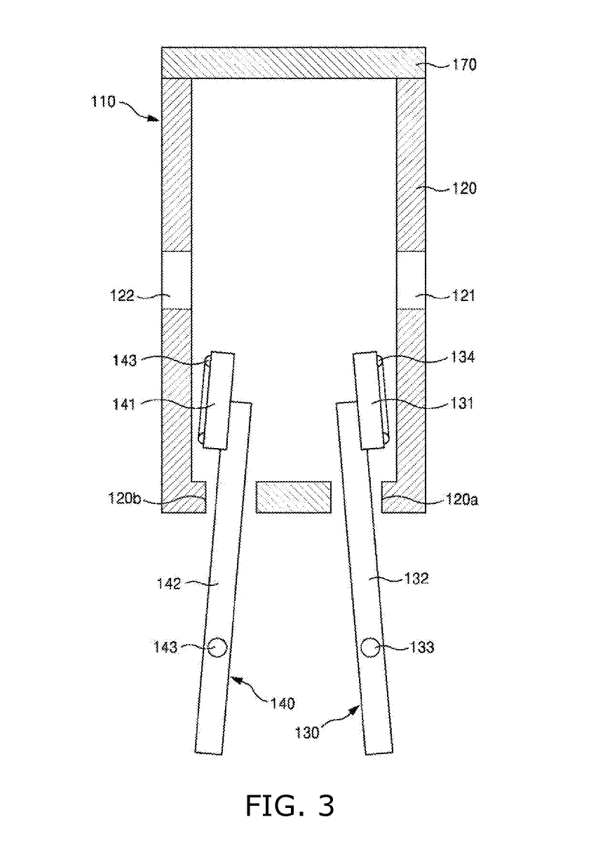

The present rectangular gate vacuum valve assembly 110 will be described in details with reference to FIG. 3 to FIG. 9.

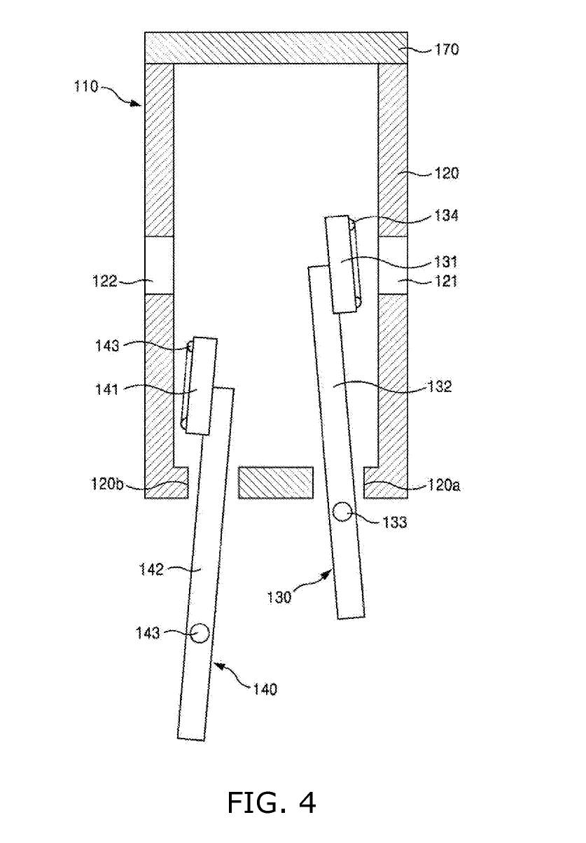

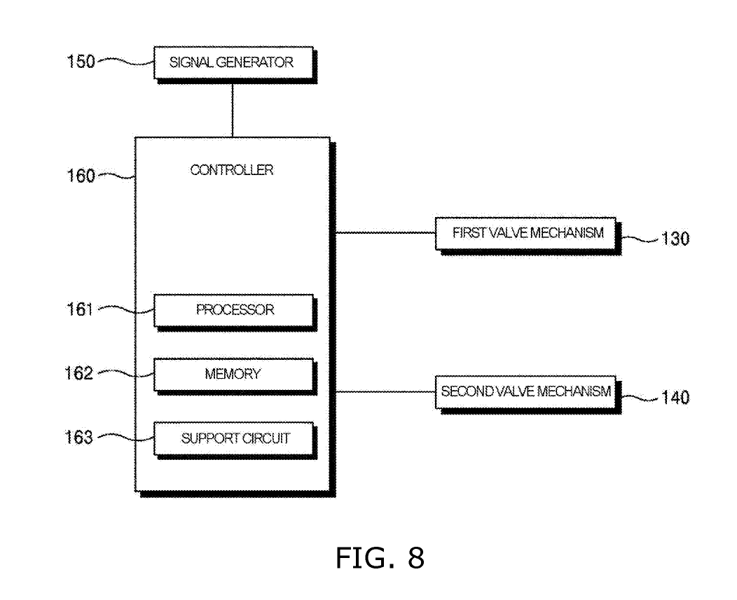

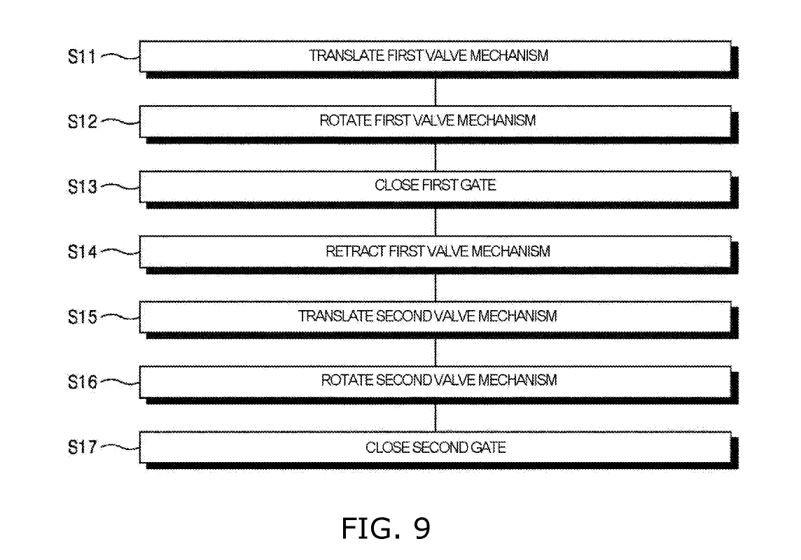

FIG. 3 is a diagram of a schematic structure of the rectangular gate vacuum valve assembly in accordance with one embodiment of the present disclosure. FIG. 4 to FIG. 7 illustrates operations of the rectangular gate vacuum valve assembly. FIG. 8 is a block diagram of a system for controlling the rectangular gate vacuum valve assembly. FIG. 9 is a flow chart of a method for operating the rectangular gate vacuum valve assembly in accordance with one embodiment of the present disclosure.

Referring to FIG. 3 to FIG. 9, the rectangular gate vacuum valve assembly 110 in accordance with one embodiment of the present disclosure may seal the opposite first and second gates 121,122 defined in the same limited space. Thus, this may be useful when the opposite first and second gates 121,122 defined in the same limited space should be sealed for the semiconductor manufacturing process. The rectangular gate vacuum valve assembly 110 in accordance with one embodiment of the present disclosure may include a gate frame 120, a first valve mechanism 130, and a second valve mechanism 140.

The gate frame 120 may be disposed between the first and second chambers 102 and 103. The gate frame 120 may have an inner space defined therein.

The gate frame 120 may have the opposite first gate 121 and second gate 122 defined at opposite side walls of the frame 120. Each of the first gate 121 and second gate 122 may have a rectangular shape as viewed from a side.

In one example, the first gate 121 and the second gate 122 may have the same size.

In another example, the first gate 121 and the second gate 122 may have different sizes.

As shown in FIG. 3 to FIG. 5, the gate frame 120 has opposite first and second gates defined in the opposite side walls respectively, wherein the gate frame 120 has first and second holes 120a and 120b defined in one of the top and bottoms walls (in this example, the holes are defined in the bottom wall although the present disclosure is limited thereto), wherein the first and second holes 120a and 120b are spaced from each other, wherein the other of the top and bottoms walls is entirely blocked using a separate blocking plate 170 (in this example, the top wall is blocked although the present disclosure is limited thereto).

The first valve mechanism 130 may be configured to translate through the first hole 120a defined at the bottom wall of the gate frame 120 in an inner space in the gate frame 120 or to rotate in an inner space in the gate frame 120 to selectively open or close the first gate 121.

The first valve mechanism 130 may include a first disk 131 configured to selectively open or close the first gate 121, a first shaft 132 coupled to the first disk 131 to translate the first disk 131, and a first rotation unit 133 operatively coupled to the first shaft 132 to rotate the first shaft 132.

The first gate 121 may be rectangular, and, hence, the first disk 131 may be rectangular. The first disk 131 may have a size larger than that of the first gate 121.

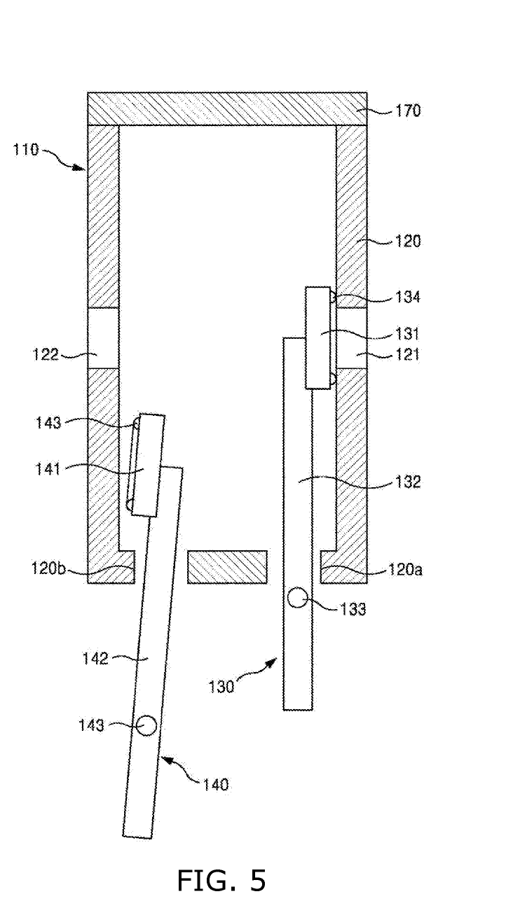

The first disk 131 may have a first sealing ring 134 attached thereto at an outer circumference. Thus, the first sealing ring 134 may be tightly attached to the first gate 121 to keep a vacuum state in the chamber as shown in FIG. 5.

The first shaft 132 may be configured to translate the first disk 131 and the first rotation unit 133 may be configured to rotate the first disk 131. A motor (not shown) may be operatively coupled to the first shaft 132. A motor (not shown) may be operatively coupled to the first rotation unit.

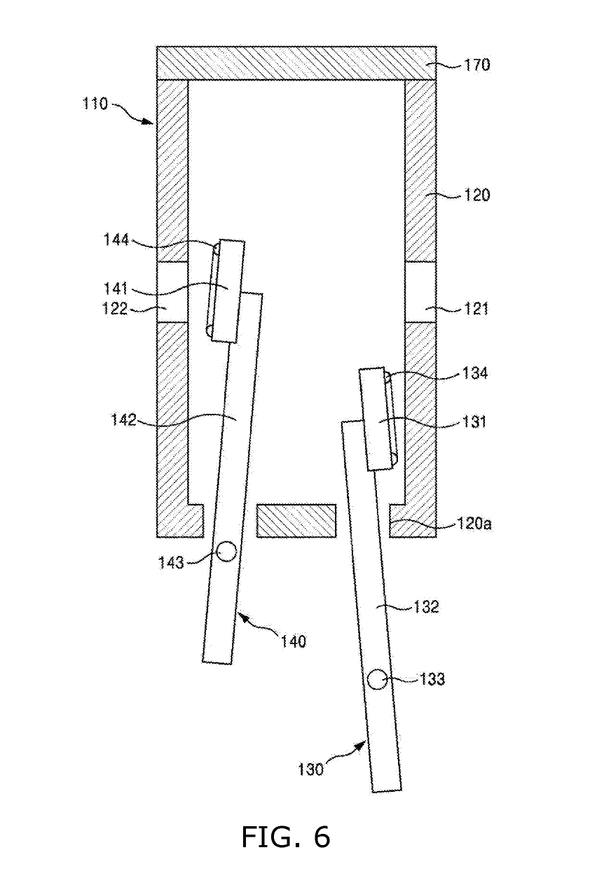

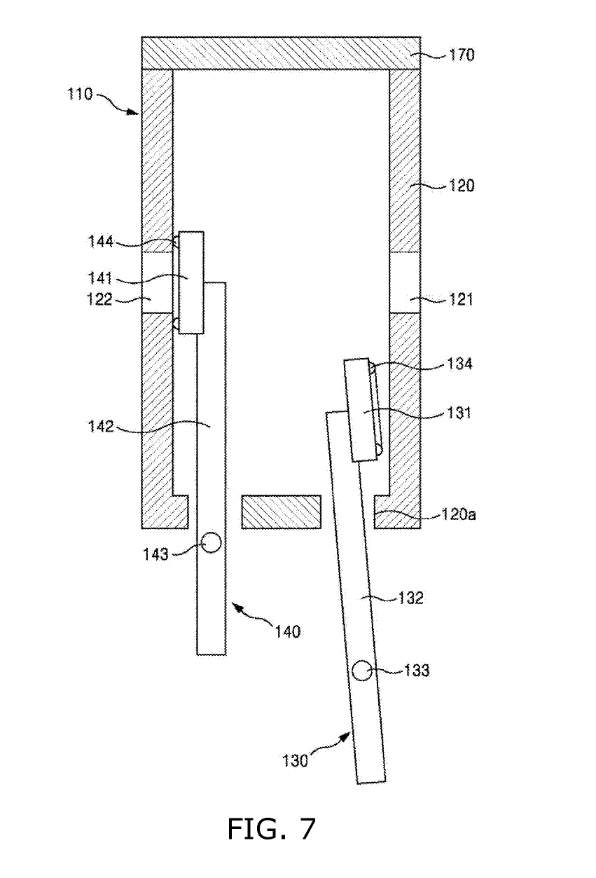

As shown in FIG. 3, FIG. 6 and FIG. 7, the second valve mechanism 140 may be configured to translate through the second hole 120b defined at the bottom wall of the gate frame 120 adjacent to the first hole 120a in an inner space in the gate frame 120 or to rotate in an inner space in the gate frame 120 to selectively open or close the second gate 122.

The second valve mechanism 140 may include a second disk 141 configured to selectively open or close the second gate 122, a second shaft 142 coupled to the second disk 141 to translate the second disk 141, and a second rotation unit 143 operatively coupled to the second shaft 142 to rotate the second shaft 142.

The second gate 122 may be rectangular, and, hence, the second disk 141 may be rectangular. The second disk 141 may have a size larger than that of the second gate 122.

The second disk 141 may have a second sealing ring 144 attached thereto at an outer circumference. Thus, the second sealing ring 144 may be tightly attached to the second gate 122 to keep a vacuum state in the chamber as shown in FIG. 7.

The second shaft 142 may be configured to translate the second disk 141 and the second rotation unit 143 may be configured to rotate the second disk 141. A motor (not shown) may be operatively coupled to the second shaft 142. A motor (not shown) may be operatively coupled to the second rotation unit.

FIG. 8 is a block diagram of a system for controlling the rectangular gate vacuum valve assembly. The system may include the rectangular gate vacuum valve assembly 110, a signal generator 150 and a controller 160. The signal generator 150 may generate a control signal to control the rectangular gate vacuum valve assembly 110 to close or open the first gate 121 and second gate 122. The control signal may be transfer to the controller 160.

The controller 160 may control an operation of the first valve mechanism 130 and second valve mechanism 140 based on the control signal from the signal generator 150. For example, based on a first control signal from the signal generator 150, the controller 160 may control the operation of the first valve mechanism 130 to close the first gate 121 as shown in FIG. 5. For example, based on a second control signal from the signal generator 150, the controller 160 may control the operation of the second valve mechanism 140 to close the second gate 122 as shown in FIG. 7.

The controller 160 may include a processor 161, a memory 162, and a supporting circuit 163.

The processor 161 may be configured to control the operation of the first valve mechanism 130 and second valve mechanism 140 based on the control signal from the signal generator 150. The processor 161 may be implemented as Complex Instruction Set Computer (CISC) or Reduced Instruction Set Computer (RISC) processors, x86 instruction set compatible processors, multi-core, or any other microprocessor or central processing unit (CPU). In embodiments, the processor 161 may comprise dual-core processor(s), dual-core mobile processor(s), and so forth.

The memory 162 may be coupled to the processor 161. The memory 162 may be implemented as a volatile memory device such as, but not limited to, a Random Access Memory (RAM), Dynamic Random Access Memory (DRAM), or Static RAM (SRAM).

The supporting circuit 163 may be coupled to the processor 161 to support the operation of the processor. The supporting circuit 163 may include a cache, a power supply, a clock circuit, an input/output circuit, and a sub-system.

The processor described in the disclosed embodiment may be implemented as a software routine written in a computer language configured to be executed by a hardware machine (such as C, C++, Fortran, Java, Basic, or the like).

The processor 161 described herein may be implemented by various means. For example, these techniques may be implemented in hardware (one or more devices), firmware (one or more devices), software (one or more modules), or combinations thereof. For a hardware implementation, the apparatus may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, digitally enhanced circuits, other electronic units designed to perform the functions described herein, or a combination thereof.

Hereinafter, operations of the present rectangular gate vacuum valve assembly 110 will be described with reference to FIG. 9.

First, the first shaft 132 of the first valve mechanism 130 together with the first disk 131 may translate through the first hole 120a of the gate frame 120 in the inner space in the gate frame 120 in a tilted manner S11.

Then, the first shaft 132 of the first valve mechanism 130 together with the first disk 131 may rotate using the first rotation unit 133 by a predetermined angle S12.

The first disk 131 may be pressed to the first gate 121 and thus the first sealing ring 134 may be air-tightly attached to the first gate 121, thereby to close the first gate 121 S13 (see FIG. 5).

Then, the first valve mechanism 130 may return to an original position S14.

Next, the second shaft 142 of the second valve mechanism 140 together with the second disk 141 may translate through the second hole 120b of the gate frame 120 in the inner space in the gate frame 120 in a tilted manner S15.

Then, the second shaft 142 of the second valve mechanism 140 together with the second disk 141 may rotate using the second rotation unit 143 by a predetermined angle S16.

The second disk 141 may be pressed to the second gate 122 and thus the second sealing ring 144 may be air-tightly attached to the second gate 122, thereby to close the second gate 122 S17 (see FIG. 7).

The operations S11 to S17 may be repeated. The operations S11 to S14 may be triggered by the first control signal from the signal generator 150. The operations S15 to S17 may be triggered by the second control signal from the signal generator 150. A group of the operations S11 to S14 may be individually carried out from a group of the operations S15 to S17.

The rectangular gate vacuum valve assembly 110 in accordance with one embodiment of the present disclosure may seal the opposite first and second gates 121,122 defined in the same limited space. Thus, this may be useful when the opposite first and second gates 121,122 defined in the same limited space should be sealed for the semiconductor manufacturing process. Further, this approach may be applied to a case wherein a space above or below the opposite top or bottom wall is not available because one of the bottom and top walls is completely blocked and is free of a hole through which the valve mechanism passes.

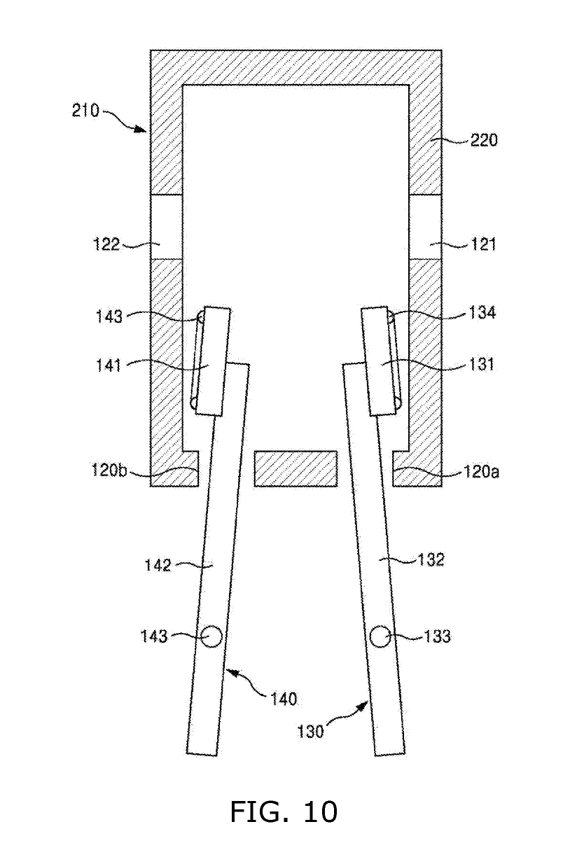

FIG. 10 is a diagram of a schematic structure of a rectangular gate vacuum valve assembly in accordance with another embodiment of the present disclosure, wherein the first and second gates are opened and a separate blocking plate is absent.

In this embodiment, the rectangular gate vacuum valve assembly 210 may include a gate frame 220 having an inner space defined therein, wherein the gate frame has opposite side walls and opposite top and bottom walls, wherein the gate frame 220 has opposite first and second gates 121 and 122 defined in the opposite side walls respectively, wherein the gate frame has first and second holes 120a and 120b defined in the bottoms wall, wherein the first and second holes are spaced from each other, wherein the top wall is entirely blocked without the blocking plate 170 as shown in FIG. 1; a first valve mechanism 130 configured to translate through the first hole in the inner space and/or to rotate in the inner space to selectively open or close the first gate; and a second valve mechanism 140 configured to translate through the second hole in the inner space and/or to rotate in the inner space to selectively open or close the second gate. That is, in this embodiment, the top wall is integrated with the gate frame 220 itself and is free of the hole.

The rectangular gate vacuum valve assembly 210 in accordance with this embodiment of the present disclosure may seal the opposite first and second gates 121,122 defined in the same limited space. Thus, this may be useful when the opposite first and second gates 121,122 defined in the same limited space should be sealed for the semiconductor manufacturing process. Further, this approach may be applied to a case wherein a space above or below the opposite top or bottom wall of the gate frame 220 is not available because one of the bottom and top walls is completely blocked and is free of a hole through which the valve mechanism passes.

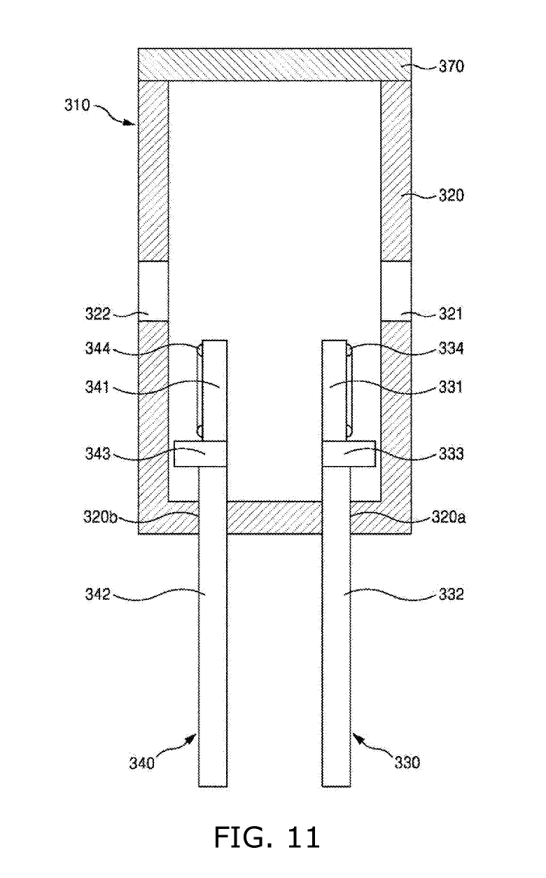

FIG. 11 to FIG. 13 illustrate operations of a rectangular gate vacuum valve assembly, in accordance with still another embodiment of the present disclosure.

In accordance with this embodiment of the present disclosure, the rectangular gate vacuum valve assembly 310 may be configured to selectively close or open first and second gates 321,322.

Referring to FIG. 11 to FIG. 13, the rectangular gate vacuum valve assembly 310 in accordance with this embodiment of the present disclosure may seal the opposite first and second gates 321,322 defined in the same limited space. Thus, this may be useful when the opposite first and second gates 321,322 defined in the same limited space should be sealed for the semiconductor manufacturing process. The rectangular gate vacuum valve assembly 310 in accordance with this embodiment of the present disclosure may include a gate frame 320, a first valve mechanism 330, and a second valve mechanism 340. The gate frame 320 may have the opposite first gate 321 and second gate 322 defined at opposite side walls of the frame 320. Each of the first gate 321 and second gate 322 may have a rectangular shape as viewed from a side. In one example, the first gate 321 and the second gate 322 may have the same size. In another example, the first gate 321 and the second gate 322 may have different sizes.

As shown in FIG. 11 to FIG. 13, the gate frame 320 has opposite first and second gates defined in the opposite side walls respectively, wherein the gate frame 320 has first and second holes 320a and 320b defined in one of the top and bottoms walls (in this example, the holes are defined in the bottom wall although the present disclosure is limited thereto), wherein the first and second holes 320a and 320b are spaced from each other, wherein the other of the top and bottoms walls is entirely blocked using a separate blocking plate 370 (in this example, the top wall is blocked although the present disclosure is limited thereto).

The first valve mechanism 330 may be configured to translate through the first hole 320a defined at the bottom wall of the gate frame 320 in an inner space in the gate frame 320 in a parallel direction to a vertical extension direction of the side walls of the gate frame. The first valve mechanism 330 may include a first bar 332 to translate through the first hole 320a in the inner space defined in the gate frame 320 in a parallel direction to a vertical extension direction of the side walls of the gate frame, a first horizontal oriented support 333 coupled to the first bar 332 at a top end thereof, and a first disk 331 configured to horizontally slide on the first horizontal oriented support 333 while supported thereon so as to selectively open or close the first gate 321.

The first gate 321 may be rectangular, and, hence, the first disk 331 may be rectangular. The first disk 331 may have a size larger than that of the first gate 321.

The first disk 331 may have a first sealing ring 334 attached thereto at an outer circumference. Thus, the first sealing ring 334 may be tightly attached to the first gate 321 to keep a vacuum state in the chamber.

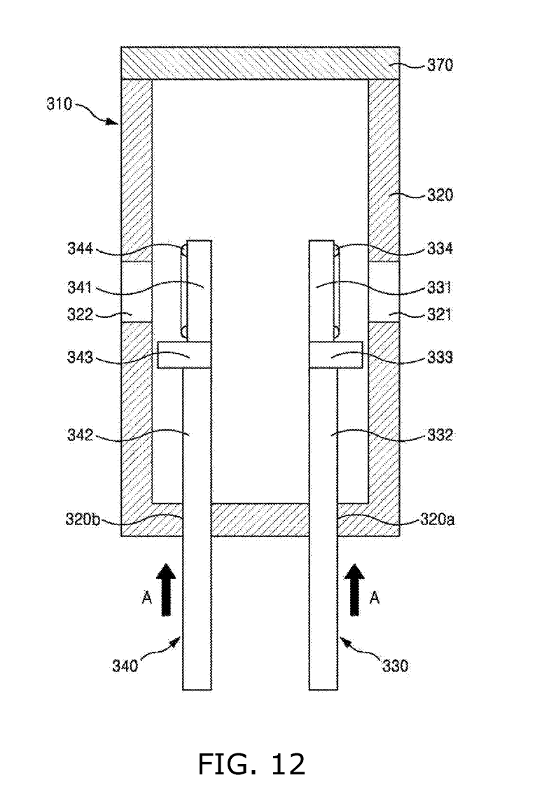

The first bar 332 may translate through the first hole 320a in a tightly-contact with the bottom wall in the inner space defined in the gate frame 320 in a parallel direction to a vertical extension direction of the side walls of the gate frame, as indicated by the arrow A in FIG. 12.

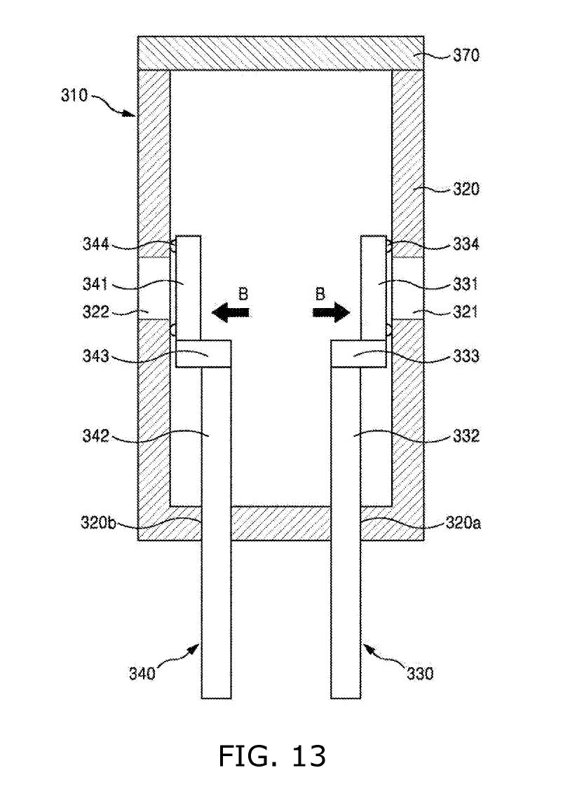

When the first horizontal oriented support 333 coupled to the first bar 332 at a top end thereof is adjacent to the first gate 321, the first disk 331 may horizontally slide on the first horizontal oriented support 333 while supported thereon so as to selectively open or close the first gate 321. For example, in the closing mode, the first disk 331 may horizontally move toward the first gate 321, while in the open mode, the first disk 331 may horizontally go away the first gate 321 as indicated by the arrow B in FIG. 13.

The second valve mechanism 340 may be configured to translate through the second hole 320b defined at the bottom wall of the gate frame 320 in an inner space in the gate frame 320 in a parallel direction to a vertical extension direction of the side walls of the gate frame. The second valve mechanism 340 may include a second bar 342 to translate through the second hole 320b in the inner space defined in the gate frame 320 in a parallel direction to a vertical extension direction of the side walls of the gate frame, a second horizontal oriented support 343 coupled to the second bar 342 at a top end thereof, and a second disk 341 configured to horizontally slide on the second horizontal oriented support 343 while supported thereon so as to selectively open or close the second gate 322.

The second gate 322 may be rectangular, and, hence, the second disk 341 may be rectangular. The second disk 341 may have a size larger than that of the second gate 322.

The second disk 341 may have a second sealing ring 344 attached thereto at an outer circumference. Thus, the second sealing ring 344 may be tightly attached to the second gate 322 to keep a vacuum state in the chamber.

The second bar 342 may translate through the second hole 320b in a tightly-contact with the bottom wall in the inner space defined in the gate frame 320 in a parallel direction to a vertical extension direction of the side walls of the gate frame, as indicated by the arrow A in FIG. 12.

When the second horizontal oriented support 343 coupled to the second bar 342 at a top end thereof is adjacent to the second gate 322, the second disk 341 may horizontally slide on the second horizontal oriented support 343 while supported thereon so as to selectively open or close the second gate 322. For example, in the closing mode, the second disk 341 may horizontally move toward the second gate 322, while in the open mode, the second disk 341 may horizontally go away the second gate 322 as indicated by the arrow B in FIG. 13.

The rectangular gate vacuum valve assembly 310 in accordance with this embodiment of the present disclosure may seal the opposite first and second gates 321,322 defined in the same limited space. Thus, this may be useful when the opposite first and second gates defined in the same limited space should be sealed for the semiconductor manufacturing process. Further, this approach may be applied to a case wherein a space above or below the opposite top or bottom wall of the gate frame 320 is not available because one of the bottom and top walls is completely blocked and is free of a hole through which the valve mechanism passes.

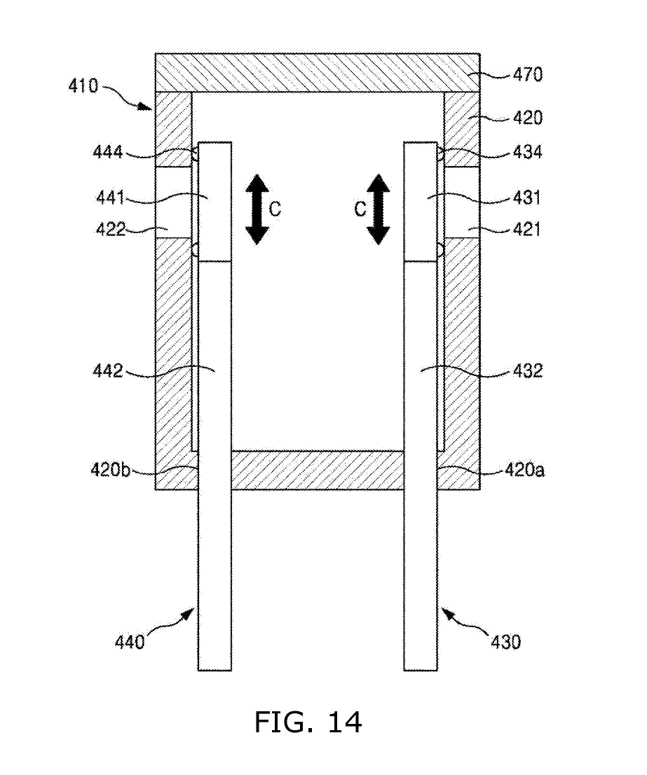

FIG. 14 is a diagram of a schematic structure of a rectangular gate vacuum valve assembly in accordance with further still another embodiment of the present disclosure, wherein the first and second gates are closed.

In accordance with this embodiment of the present disclosure, the rectangular gate vacuum valve assembly 410 may be configured to selectively close or open first and second gates 421,422.

Referring to FIG. 14, the rectangular gate vacuum valve assembly 410 in accordance with this embodiment of the present disclosure may seal the opposite first and second gates 421,422 defined in the same limited space. Thus, this may be useful when the opposite first and second gates 421,422 defined in the same limited space should be sealed for the semiconductor manufacturing process. The rectangular gate vacuum valve assembly 410 in accordance with this embodiment of the present disclosure may include a gate frame 420, a first valve mechanism 430, and a second valve mechanism 440. The gate frame 420 may have the opposite first gate 421 and second gate 422 defined at opposite side walls of the frame 420. Each of the first gate 421 and second gate 422 may have a rectangular shape as viewed from a side. In one example, the first gate 421 and the second gate 422 may have the same size. In another example, the first gate 421 and the second gate 422 may have different sizes.

As shown in FIG. 14, the gate frame 420 has opposite first and second gates defined in the opposite side walls respectively, wherein the gate frame 420 has first and second holes 420a and 420b defined in one of the top and bottoms walls (in this example, the holes are defined in the bottom wall although the present disclosure is limited thereto), wherein the first and second holes 420a and 420b are spaced from each other, wherein the other of the top and bottoms walls is entirely blocked using a separate blocking plate 470 (in this example, the top wall is blocked although the present disclosure is limited thereto).

The first valve mechanism 430 may be configured to translate through the first hole 420a defined at the bottom wall of the gate frame 420 in an inner space in the gate frame 420 in a parallel direction to a vertical extension direction of the side walls of the gate frame. The first valve mechanism 430 may include a first bar 432 to translate through the first hole 420a in the inner space defined in the gate frame 420 in a parallel direction to a vertical extension direction of the side walls of the gate frame, and a first disk 431 fixed to the first bar 432 at the top end thereof. The first gate 421 may be rectangular, and, hence, the first disk 431 may be rectangular. The first disk 431 may have a size larger than that of the first gate 421.

The first disk 431 may have a first sealing ring 434 attached thereto at an outer circumference. Thus, the first sealing ring 434 may be tightly attached to the first gate 421 to keep a vacuum state in the chamber.

The first bar 432 may translate through the first hole 420a in a tightly-contact with the bottom wall in the inner space defined in the gate frame 420 in a parallel direction to a vertical extension direction of the side walls of the gate frame while the first sealing ring 434 tightly contact the inner side face of the left side wall, as indicated by the arrow C in FIG. 14.

When the first disk 431 coupled to the first bar 432 at a top end thereof is adjacent to the first gate 421, the first sealing ring 434 tightly contact the inner side face of the left side wall around the first gate 421, thereby to close the first gate 421.

The second valve mechanism 440 may be configured to translate through the second hole 420b defined at the bottom wall of the gate frame 420 in an inner space in the gate frame 420 in a parallel direction to a vertical extension direction of the side walls of the gate frame. The second valve mechanism 440 may include a second bar 442 to translate through the second hole 420b in the inner space defined in the gate frame 420 in a parallel direction to a vertical extension direction of the side walls of the gate frame, and a second disk 441 fixed to the second bar 442 at the top end thereof. The second gate 422 may be rectangular, and, hence, the second disk 441 may be rectangular. The second disk 441 may have a size larger than that of the second gate 422.

The second disk 441 may have a second sealing ring 444 attached thereto at an outer circumference. Thus, the second sealing ring 444 may be tightly attached to the second gate 422 to keep a vacuum state in the chamber.

The second bar 442 may translate through the second hole 420b in a tightly-contact with the bottom wall in the inner space defined in the gate frame 420 in a parallel direction to a vertical extension direction of the side walls of the gate frame while the second sealing ring 444 tightly contact the inner side face of the right side wall, as indicated by the arrow C in FIG. 14.

When the second disk 441 coupled to the second bar 442 at a top end thereof is adjacent to the second gate 422, the second sealing ring 444 tightly contact the inner side face of the right side wall around the second gate 422, thereby to close the second gate 422.

The rectangular gate vacuum valve assembly 410 in accordance with this embodiment of the present disclosure may seal the opposite first and second gates 421,422 defined in the same limited space. Thus, this may be useful when the opposite first and second gates defined in the same limited space should be sealed for the semiconductor manufacturing process. Further, this approach may be applied to a case wherein a space above or below the opposite top or bottom wall of the gate frame 420 is not available because one of the bottom and top walls is completely blocked and is free of a hole through which the valve mechanism passes.

Examples of various embodiments has been illustrated and described above. It will be understood that the description herein is not intended to limit the claims to the specific embodiments described. On the contrary, it is intended to cover alternatives, modifications, and equivalents as may be included within the spirit and scope of the present disclosure as defined by the appended claims.

In order to prevent the conflict between the first valve mechanism and second valve mechanism, the first valve mechanism and second valve mechanism may be operated in an alternate manner.

The above description is not to be taken in a limiting sense, but is made merely for the purpose of describing the general principles of exemplary embodiments, and many additional embodiments of this disclosure are possible. It is understood that no limitation of the scope of the disclosure is thereby intended. The scope of the disclosure should be determined with reference to the Claims. Reference throughout this specification to “one embodiment,” “an embodiment,” or similar language means that a particular feature, structure, or characteristic that is described in connection with the embodiment is included in at least one embodiment of the present disclosure. Thus, appearances of the phrases “in one embodiment,” “in an embodiment,” and similar language throughout this specification may, but do not necessarily, all refer to the same embodiment.

### INDUSTRIAL-ABILITY

The present rectangular gate vacuum valve assembly may seal the opposite first and second gates defined in the same limited space. Thus, this may be useful when the opposite first and second gates defined in the same limited space should be sealed for the semiconductor manufacturing process. Further, this approach may be applied to a case wherein a space above or below the opposite top or bottom wall is not available.

What is claimed is:

1. A rectangular gate vacuum valve assembly comprising:
a gate frame having an inner space defined therein, wherein the gate frame has opposite side walls and opposite top and bottom walls, wherein the gate frame has opposite first and second gates defined in the opposite side walls respectively, wherein the gate frame has first and second holes defined in one of the top and bottoms walls, wherein the first and second holes are spaced from each other, wherein the other of the top and bottoms walls is entirely blocked;
a first valve mechanism configured to translate through the first hole in the inner space and/or to rotate in the inner space to selectively open or close the first gate; and
a second valve mechanism configured to translate through the second hole in the inner space and/or to rotate in the inner space to selectively open or close the second gate.

2. The assembly of claim 1, wherein the first valve mechanism comprises:
a first disk configured to selectively open or close the first gate;
a first shaft coupled to the first disk to translate the first disk; and
a first rotation unit coupled to the first shaft to rotate the first shaft.

3. The assembly of claim 2, wherein the second valve mechanism comprises:
a second disk configured to selectively open or close the second gate;
a second shaft coupled to the second disk to translate the second disk; and
a second rotation unit coupled to the second shaft to rotate the second shaft.

4. The assembly of claim 3, wherein each of the first and second disks has a sealing ring attached thereto.

5. The assembly of claim 1, wherein the first and second gates have the same size or different sizes.

6. A system for a rectangular gate vacuum valve assembly, the system comprising:
the assembly of claim 1;
a signal generator configured to generate a control signal to allow closing and opening of the first and second gates; and
a controller configured to control operations of the first and second valve mechanisms based on the control signal from the signal generator.

7. A semiconductor manufacturing apparatus comprising:
first and second vacuum chambers spaced from each other where a semiconductor manufacturing process is conducted; and
a rectangular gate vacuum valve assembly disposed between the first and second vacuum chambers, wherein the rectangular gate vacuum valve assembly is configured to selectively close or open first and second gates communicating with the first and second vacuum chambers respectively,
wherein the rectangular gate vacuum valve assembly comprises:
a gate frame having an inner space defined therein, wherein the gate frame has opposite side walls and opposite top and bottom walls, wherein the gate frame has the opposite first and second gates defined in the opposite side walls respectively, wherein the gate frame has first and second holes defined in one of the top and bottoms walls, wherein the first and second holes are spaced from each other, wherein the other of the top and bottoms walls is entirely blocked;
a first valve mechanism configured to translate through the first hole in the inner space and/or to rotate in the inner space to selectively open or close the first gate; and
a second valve mechanism configured to translate through the second hole in the inner space and/or to rotate in the inner space to selectively open or close the second gate.

8. The apparatus of claim 7, wherein the first valve mechanism comprises:
a first disk configured to selectively open or close the first gate;
a first shaft coupled to the first disk to translate the first disk; and
a first rotation unit coupled to the first shaft to rotate the first shaft,
wherein the second valve mechanism comprises:
a second disk configured to selectively open or close the second gate;
a second shaft coupled to the second disk to translate the second disk; and
a second rotation unit coupled to the second shaft to rotate the second shaft,
wherein each of the first and second disks has a sealing ring attached thereto.
